(19) United States
(12) Patent Application Publication
(10) Pub. No.: US 2017/0170099 A1
(43) Pub. Date: Jun. 15, 2017

(54) INTERPOSER STRUCTURE AND MANUFACTURING METHOD THEREOF

(71) Applicant: I-SHOU UNIVERSITY, KAOHSIUNG CITY (TW)

(72) Inventors: Yu-Jung Huang, KAOHSIUNG CITY (TW); Wei-Han Huang, KAOHSIUNG CITY (TW)

(21) Appl. No.: 14/983,574

(22) Filed: Dec. 30, 2015

(30) Foreign Application Priority Data
Dec. 11, 2015 (TW) 104141631

(51) Int. Cl. H01L 23/498; H01L 21/027; H01L 21/48

(52) U.S. Cl. CPC H01L 23/4985; H01L 23/49838; H01L 23/49827; H01L 23/49811; H01L 21/486; H01L 21/4853; H01L 21/0273; H01L 23/49894

(57) ABSTRACT

An interposer structure and a manufacturing method thereof are provided. The interposer structure includes a flexible substrate, a plurality of conductive pillars, a first patterned conductive layer, and a second patterned conductive layer. The flexible substrate includes a first surface and a second surface opposite to the first surface and has a plurality of through holes extending from the first surface to the second surface. A material of the flexible substrate is an insulator. The conductive pillars are disposed in the through holes. The first patterned conductive layer is disposed on the first surface of the flexible substrate and is electrically connected to the conductive pillars. The second patterned conductive layer is disposed on the second surface of the flexible substrate and is electrically connected to the conductive pillars.

### CROSS REFERENCE TO RELATED APPLICATION

This application claims the priority benefit of Taiwan application serial no. 104141631, filed on Dec. 11, 2015. The entirety of the above-mentioned patent application is hereby incorporated by reference herein and made a part of specification.

### BACKGROUND OF THE INVENTION

1. Field of the Invention

The present invention relates to an interposer structure, and in particular, to an interposer structure having a flexible substrate.

2. Description of Related Art

With the development of integrated circuits so far, because integration density of various electronic components keeps increasing, the semiconductor industry has undergone continuous and rapid growth. These improvements made in integration density are mostly owing to multiple times of reductions in size, so that more elements are integrated within a particular area. An interposer may be used as a conducting platform between heterogeneous chips, so as to implement integration of the elements within the particular area.

A conventional interposer material is mainly silicon or glass; however, silicon and glass have relatively high dielectric constants, resulting in a decrease in a transmission speed of a signal between heterogeneous chips, thereby causing a delay in transmission of the signal in an integrated circuit. In addition, silicon and glass also have relatively poor flexibility, thus cannot meet requirements of future wearable products. In another aspect, conventional manner of fabricating an interposer structure would render metal bumps disposed on the interposer structure to have a same thickness, and therefore the interposer is not applicable to connection points of different heights.

### SUMMARY OF THE INVENTION

The present invention provides an interposer structure and a manufacturing method thereof, so that a transmission speed of a signal can be effectively increased, and the present invention is applicable for wider uses.

The present invention provides an interposer structure, including a flexible substrate, a plurality of conductive pillars, a first patterned conductive layer, and a second patterned conductive layer. The flexible substrate includes a first surface and a second surface opposite to the first surface and has a plurality of through holes. The through holes extend from the first surface to the second surface. A material of the flexible substrate is an insulator. The conductive pillars are disposed in the through holes. The first patterned conductive layer is disposed on the first surface of the flexible substrate and is electrically connected to the conductive pillars. The second patterned conductive layer is disposed on the second surface of the flexible substrate and is electrically connected to the conductive pillars.

In an embodiment of the present invention, the first patterned conductive layer further includes a plurality of first conductive bumps and a plurality of second conductive bumps. At least one of the first conductive bumps and the second conductive bumps is electrically connected to the conductive pillars. The second patterned conductive layer further includes a plurality of third conductive bumps and a plurality of fourth conductive bumps. At least one of the third conductive bumps and the fourth conductive bumps is electrically connected to the conductive pillars.

In an embodiment of the present invention, the first conductive bumps and the second conductive bumps have a same thickness.

In an embodiment of the present invention, the first conductive bumps and the second conductive bumps have different thicknesses.

In an embodiment of the present invention, the material of the flexible substrate is polyimide (PI) or polyethylene terephthalate (PET).

In an embodiment of the present invention, a thickness of the flexible substrate is 7.5 μm to 400 μm.

The present invention provides a manufacturing method of an interposer structure. First, a flexible substrate is provided. The flexible substrate includes a first surface and a second surface opposite to the first surface, and a material of the flexible substrate is an insulator. Next, a plurality of through holes is formed in the flexible substrate, and a first seed layer is formed on the first surface and in the through holes of the flexible substrate. A conductive material is filled in the through holes to form a plurality of conductive pillars. Subsequently, a first patterned conductive layer is formed on the first seed layer, and the first patterned conductive layer is electrically connected to the conductive pillars. The first seed layer is removed and a second seed layer is formed on the second surface of the flexible substrate. A second patterned conductive layer is formed on the second seed layer, and the second patterned conductive layer is electrically connected to the conductive pillars. Next, the second seed layer is removed.

In an embodiment of the present invention, the step of forming the first patterned conductive layer includes forming a first patterned photoresist layer on the first seed layer, and the first patterned photoresist layer has a plurality of openings. Next, a first metal layer material is filled in the openings, and the first patterned photoresist layer is removed to form the first patterned conductive layer.

In an embodiment of the present invention, the step of forming the first patterned conductive layer includes forming a first patterned photoresist layer on the first seed layer, and the first patterned photoresist layer has a plurality of openings. Next, a first metal layer material is filled in the openings, and the first patterned photoresist layer is removed to form a plurality of first conductive bumps. Subsequently, a second patterned photoresist layer is formed on the first surface of the flexible substrate, and the second patterned photoresist layer exposes at least one of the first conductive bumps. A metal material is formed on the exposed first conductive bumps to Bolin a plurality of second conductive bumps. Next, the second patterned photoresist layer is removed to form the first patterned conductive layer, and the first patterned conductive layer includes the first conductive bumps and the second conductive bumps.

In an embodiment of the present invention, a thickness of the second conductive bumps is greater than a thickness of the first conductive bumps.

In an embodiment of the present invention, the material of the flexible substrate is polyimide (PI) or polyethylene terephthalate (PET).

Based on the above, in the interposer structure of the present invention, by using the flexible substrate having a lower dielectric constant, the conductivity and heat dissipation of the interposer structure can be effectively improved, thereby providing a semiconductor device with higher reliability. In another aspect, since the interposer structure of the present invention includes metal bumps having different heights, the interposer structure of the present invention is suitable for use on connection points having height differences, and is therefore applicable for wider uses.

In order to make the aforementioned and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1S are schematic cross-sectional views of a manufacturing process of an interposer structure according to an embodiment of the present invention.

FIG. 2A to FIG. 2C are schematic cross-sectional views of part of a manufacturing process of an interposer structure according to another embodiment of the present invention.

FIG. 2D is a schematic cross-sectional view of an interposer structure according to the embodiment in FIG. 2A to FIG. 2C.

FIG. 3A to FIG. 3C are schematic cross-sectional views of part of a manufacturing process of an interposer structure according to still another embodiment of the present invention.

FIG. 3D is a schematic cross-sectional view of an interposer structure according to the embodiment in FIG. 3A to FIG. 3C.

FIG. 4 is a schematic cross-sectional view of an interposer structure according to yet another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

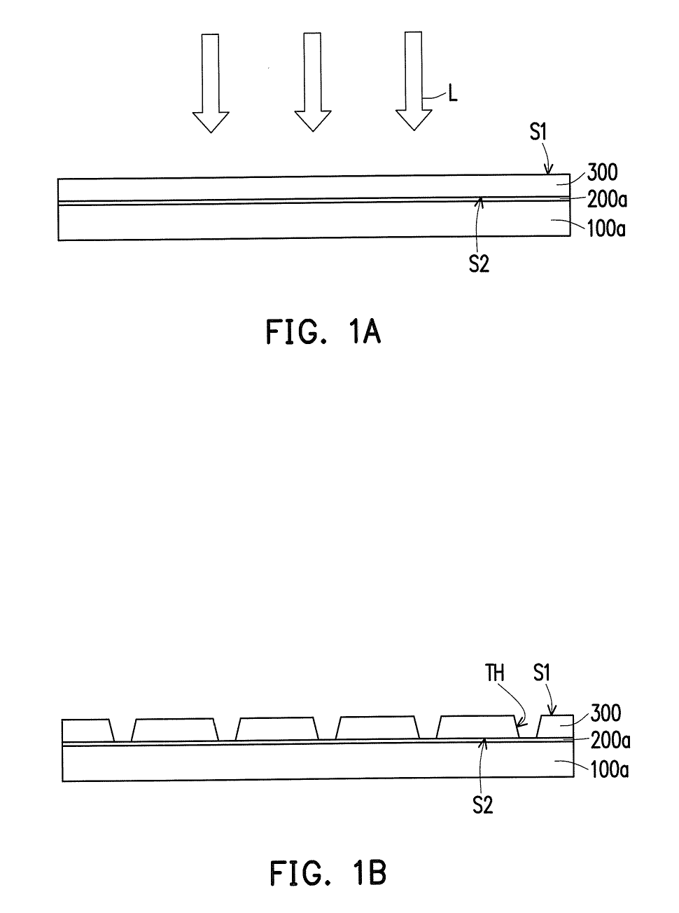

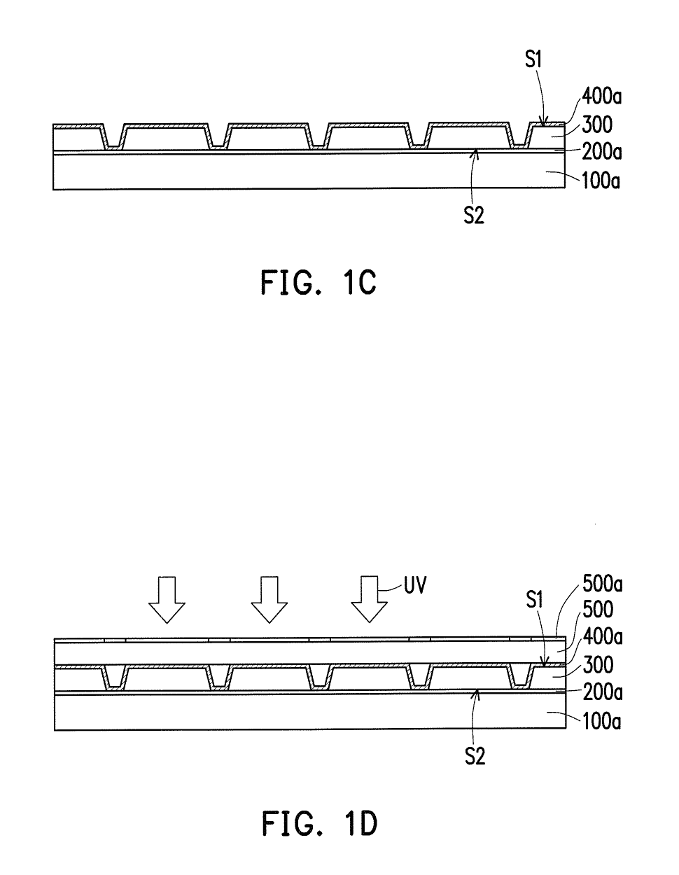

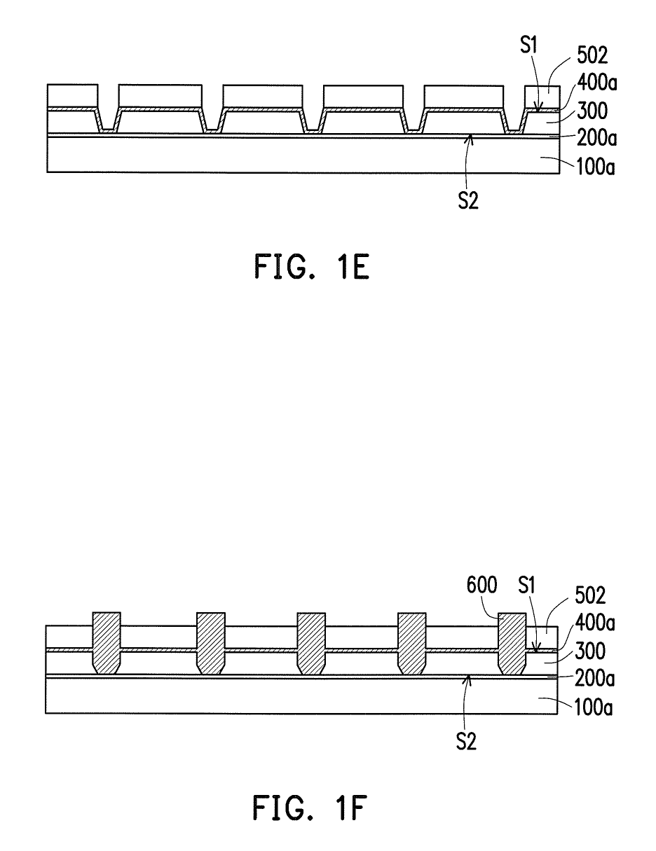

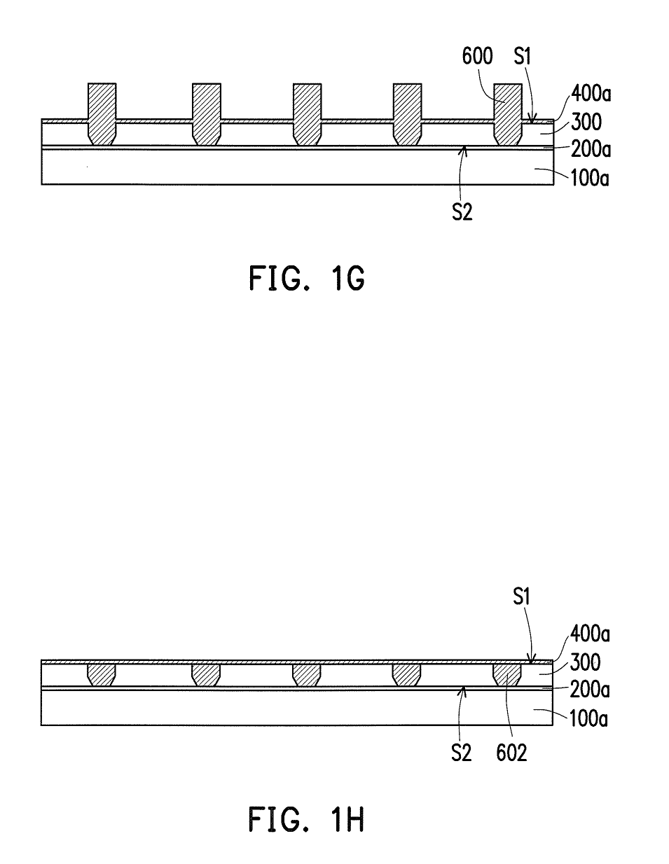

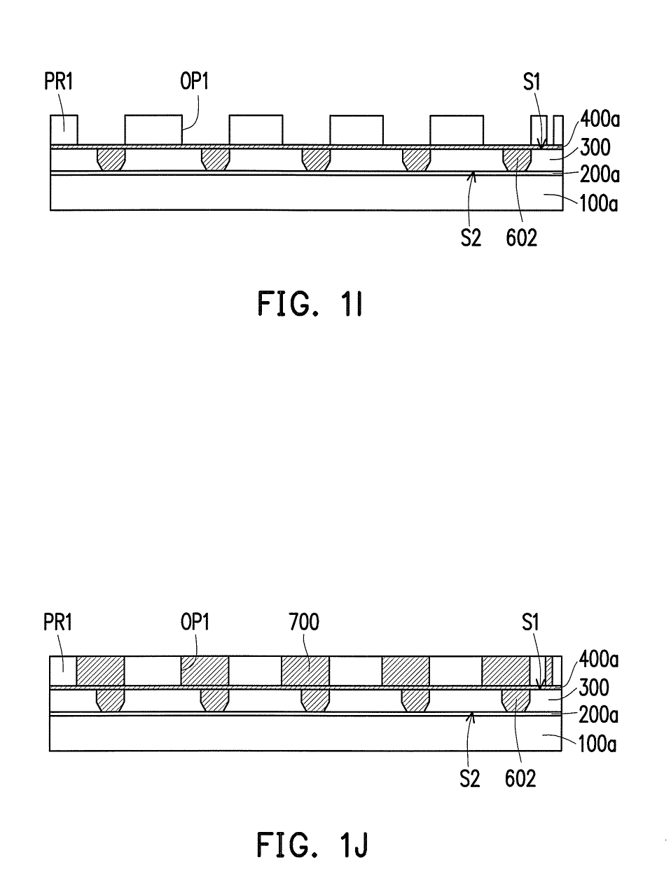

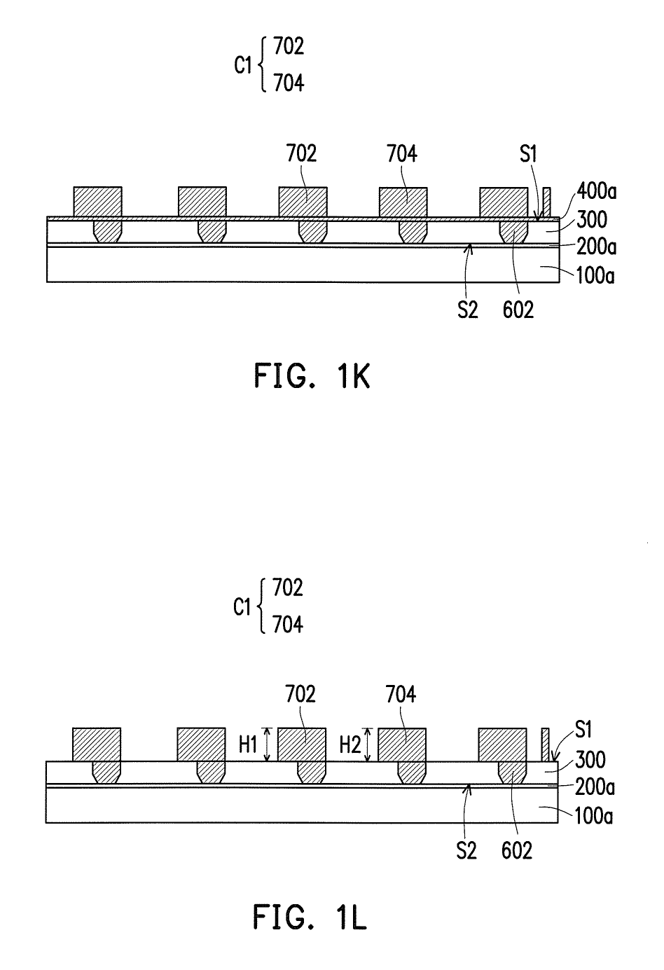

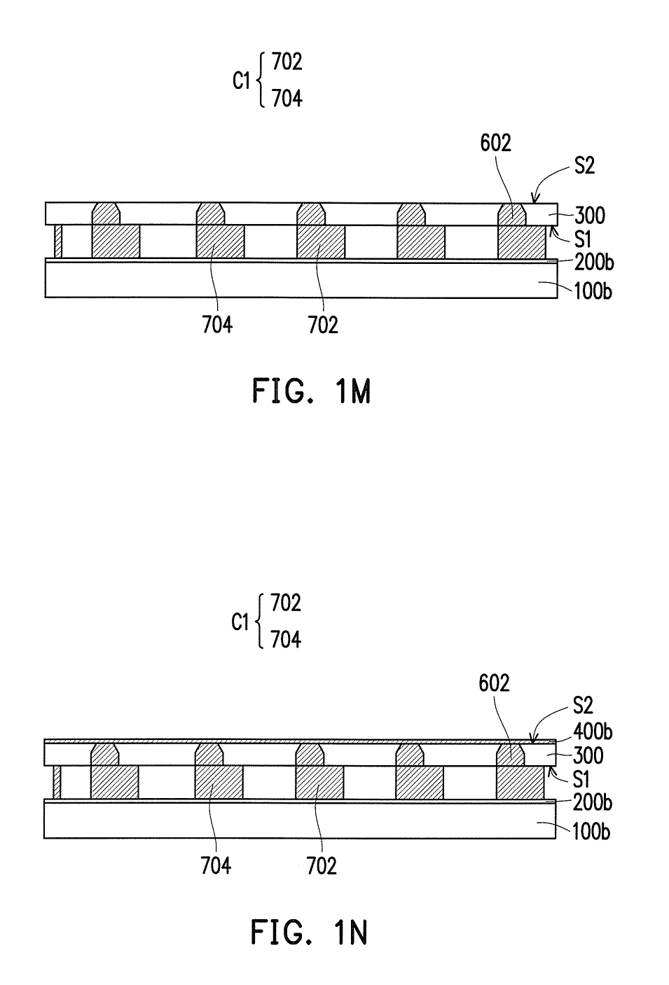

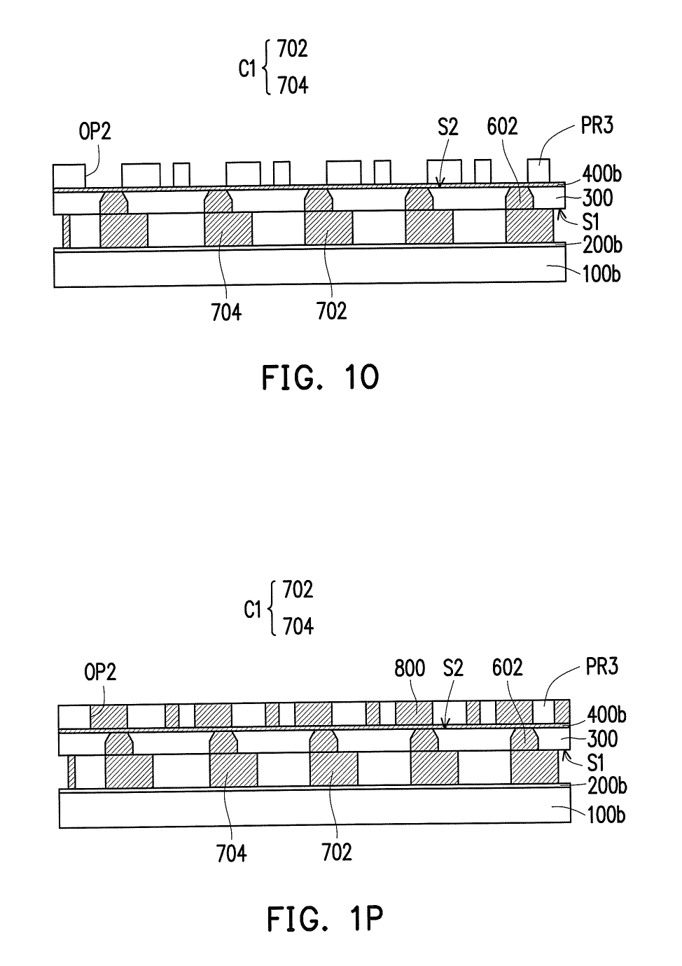

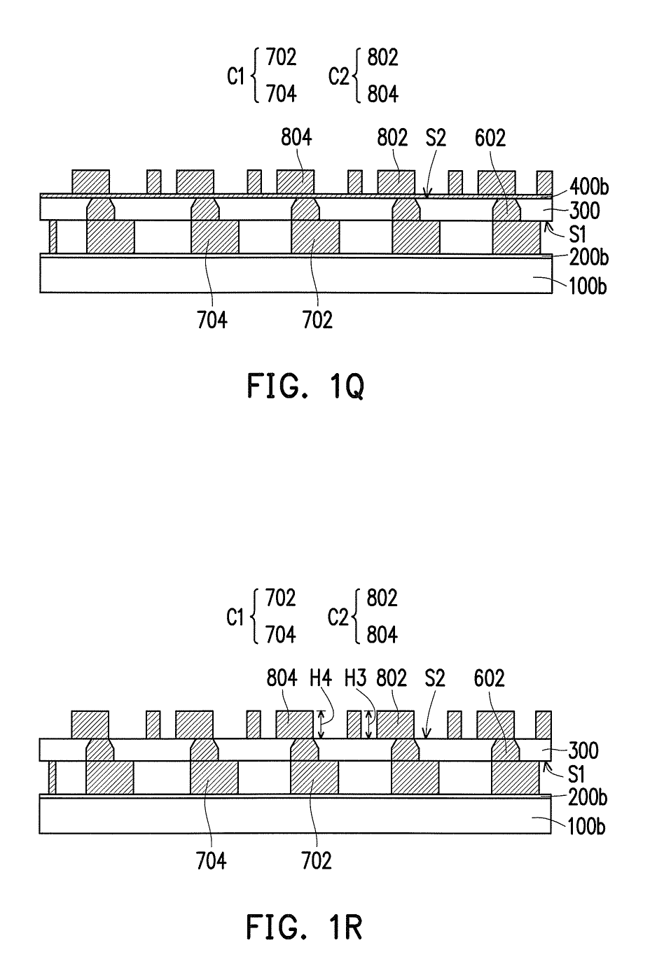

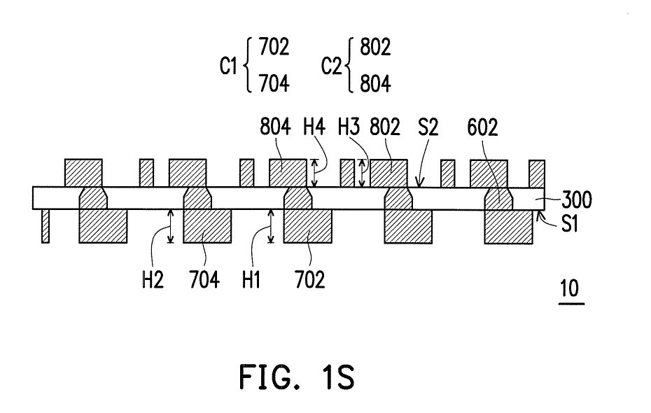

FIG. 1A to FIG. 1S are schematic cross-sectional views of a manufacturing process of an interposer structure 10 according to an embodiment of the present invention. Referring to FIG. 1A, first, a first carrier substrate 100a is provided, and a first buffer layer 200a and a flexible substrate 300 are sequentially formed on the first carrier substrate 100a. The first carrier substrate 100a is, for example, a glass substrate, a silicon substrate, a ceramic substrate or a silicon carbide substrate. A material of the first carrier substrate 100a is not particularly limited in the present invention, as long as the first carrier substrate 100a can carry the first buffer layer 200a and the flexible substrate 300. A material of the first buffer layer 200a may be a photoresist material. In the present embodiment, an S1818 photoresist is used as the material of the first buffer layer 200a, but the present invention is not limited thereto. In other embodiments, other suitable photoresist materials may also be used as the material of the first buffer layer 200a.

The flexible substrate 300 is an insulator, and has a first surface S1 and a second surface S2 opposite to the first surface S1. A material of the flexible substrate 300 is, for example, polyimide (PI) or polyethylene terephthalate (PET), but the present invention is not limited thereto. A dielectric constant of the flexible substrate 300 is between 2.8 and 3.2, and the flexible substrate 300 has a peel strength of 0.7 kgf/cm to 1.5 kgf/cm and an insulation resistance of 1×10¹² Ωcm to 1×10¹⁵ Ωcm. In another aspect, to ensure flexibility of the flexible substrate 300, a thickness of the flexible substrate 300 is about 7.5 μm to 400 μm, and is preferably between 11.25 μm and 13.75 μm. Before the flexible substrate 300 is formed on the first buffer layer 200a, a pre-treatment process may be performed on the flexible substrate 300 to remove moisture on the flexible substrate 300. Specifically, the pre-treatment process includes first washing the flexible substrate 300 by deionized (DI) water and ethanol, and the flexible substrate 300 is then dried by nitrogen gas. Subsequently, the flexible substrate 300 is heated to 110° C. and is baked for 10 minutes to ensure that all moisture is evaporated.

Next, a laser beam L is used to perform a drilling procedure on the flexible substrate 300 to form a plurality of through holes TH in the flexible substrate 300, as shown in FIG. 1B. The through holes TH penetrate through the flexible substrate 300 and extend from the first surface S1 to the second surface S2. In the present embodiment, the laser beam L includes ultraviolet (UV) Nd:YAG laser, but the present invention is not limited thereto. Other suitable laser may also be used as the laser beam L of the present invention. It should be noted that, in the present embodiment, the drilling process is exemplified by a laser drilling process, but the present invention is not limited thereto. In other embodiments, a mechanical drilling process or a patterning process may also be used to form the through holes TH.

Referring to FIG. 1C, a first seed layer 400a is formed on the first surface S1 and the in through holes TH of the flexible substrate 300. A material of the first seed layer 400a is, for example, copper, titanium, tantalum, tungsten, aluminum or an alloy thereof. A method of forming the first seed layer 400a is, for example, an electroless plating process, a chemical plating process, a thermal evaporation process, and a sputtering process, but the present invention is not limited thereto. In the present embodiment, thermal evaporation process is performed under a pressure of 10⁻⁶ Torr, and the first seed layer 400a having a thickness of 200 nm is formed at a deposition rate of 3-5 Å/s. The first seed layer 400a can facilitate the deposition of other metal layers on the flexible substrate 300 in subsequent processes.

Referring to FIG. 1D, a photoresist material layer 500 is formed on the first seed layer 400a. The photoresist material layer 500 is, for example, photosensitive resin or other photosensitive material. For example, in the present embodiment, an AZ4620 photoresist is used as the photoresist material layer 500, but the present invention is not limited thereto. Moreover, in the present embodiment, the photoresist material layer 500 having a thickness of 6 μm is formed on the first seed layer 400a by using spin coating at a rotating speed of 3000 rpm, but the present invention is not limited thereto. Other suitable coating method may also be used to form the photoresist material layer 500.

Next, a patterning mask 500a is used as a mask, and an ultraviolet light UV is used in combination to perform an exposure process on the photoresist material layer 500 to form a photoresist layer 502, as shown in FIG. 1E. In the present embodiment, a wavelength of the ultraviolet light UV is between 350 nm and 450 nm, and has an intensity of 100 mJ/cm², but the present invention is not limited thereto. The wavelength and the intensity of the ultraviolet light UV may be adjusted according to the photoresist material layer 500 used. In addition, referring to FIG. 1E, the photoresist layer 502 exposes the first seed layer 400a inside the through holes TH.

Referring to FIG. 1F, after the photoresist layer 502 is formed, a conductive material 600 is filled in the through holes TH. As discussed above, because the photoresist layer 502 only exposes the through holes TH, the photoresist layer 502 may be used as a mask such that the conductive material 600 is filled in the through holes TH only. In the present embodiment, copper is used as an example for the conductive material 600, but the present invention is not limited thereto. In other embodiments, a material of the conductive material 600 may also be titanium, tantalum, tungsten, aluminum or an alloy thereof. On the other hand, the process of forming the conductive material 600 is, for example, an electroplating process or a deposition process, so as to fill the conductive material 600 in the through holes TH.

Next, referring to FIG. 1G and FIG. 1H at the same time, the photoresist layer 502 is removed and a thickness of the conductive material 600 is reduced to form conductive pillars 602 located inside the through holes TH. A method of reducing the thickness of the conductive material 600 is, for example, chemical mechanical polishing (CMP), but the present invention is not limited thereto.

Referring to FIG. 1I, after the conductive pillars 602 are formed, a first patterned photoresist layer PR1 is formed on the first seed layer 400a. The first patterned photoresist layer PR1 has a plurality of openings OP1, and at least one opening OP1 is provided corresponding to the conductive pillars 602. Reference may be made to the photoresist layer 502 for a material and a forming method of the first patterned photoresist layer PR1, and the descriptions thereof are omitted herein.

Next, referring to FIG. 1J, a first metal material layer 700 is filled in the openings OP1. A material of the first metal material layer 700 may be the same as or different from the material of the conductive material 600. Specifically, the material of the first metal material layer 700 is, for example, copper, titanium, tantalum, tungsten, aluminum or an alloy thereof. As discussed above, because the openings OP1 of the first patterned photoresist layer PR1 are disposed corresponding to the conductive pillars 602, the first metal material layer 700 filled in the openings OP1 is electrically connected to the conductive pillars 602. After the first metal material layer 700 is formed, the first patterned photoresist layer PR1 is removed to form a first patterned conductive layer C1, as shown in FIG. 1K. The first patterned conductive layer C1 includes a plurality of first conductive bumps 702 and a plurality of second conductive bumps 704. In the embodiment in FIG. 1K, because all the openings OP1 are not disposed corresponding to the conductive pillars 602, not all the first conductive bumps 702 and the second conductive bumps 704 are connected to the conductive pillars 602. In other words, in the present embodiment, as long as at least one first conductive bump 702 or at least one second conductive bump 704 is connected to the conductive pillars 602, the rest first conductive bumps 702 and second conductive bumps 704 may be separated from to the conductive pillars 602. However, the present invention is not limited thereto. In other embodiments, all of the first conductive bumps 702 and the second conductive bumps 704 can be electrically connected to different conductive pillars 602 respectively.

Next, referring to FIG. 1L, dry etching or wet etching is used to remove a part of the first seed layer 400a not covered by the first conductive bumps 702 or the second conductive bumps 704. In this step, the process on the first surface S1 of the flexible substrate 300 is basically completed. It should be noted that, the steps in FIG. 1B to FIG. 1L are also referred to as a semi-additive process (SAP), so that fine traces can be effectively formed. In another aspect, in the present embodiment, because the first conductive bumps 702 and the second conductive bumps 704 are formed by using the same first patterned photoresist layer PR1, a thickness H1 of the first conductive bumps 702 is equal to a thickness H2 of the second conductive bumps 704.

Referring to FIG. 1M, the flexible substrate 300 is separated from the first buffer layer 200a and the first carrier substrate 100a, and the flexible substrate 300 is turned over, so as to perform another semi-additive process on the second surface S2. Specifically, a second carrier substrate 100b and a second buffer layer 200b disposed on the second carrier substrate 100b are provided, and the first conductive bumps 702 and the second conductive bumps 704 are placed on the second buffer layer 200b, so as to perform the semi-additive process on the second surface S2 of the flexible substrate 300. Materials of the second carrier substrate 100b and the second buffer layer 200b may be similar to materials of the first carrier substrate 100a and the first buffer layer 200a respectively, and the detailed descriptions are omitted herein. The semi-additive process on the second surface S2 is described below.

Referring to FIG. 1N, a second seed layer 400b is first formed on the second surface S2 of the flexible substrate 300. Similar to the first seed layer 400a, a material of the second seed layer 400b is, for example, copper, titanium, tantalum, tungsten, aluminum or an alloy thereof, and a method of Ruining the second seed layer 400b is, for example, an electroless plating process, a chemical plating process, a thermal evaporation process , and a sputtering process.

Next, a third patterned photoresist layer PR3 is formed on the second seed layer 400b, as shown in FIG. 1O. The third patterned photoresist layer PR3 has a plurality of openings OP2, and at least one opening OP2 is disposed corresponding to the conductive pillars 602. Reference may be made to the first patterned photoresist layer PR1 and the photoresist layer 502 for a material and a forming method of the third patterned photoresist layer PR3, and the descriptions thereof are omitted herein.

Referring to FIG. 1P, a second metal material layer 800 is filled in the openings OP2 of the third patterned photoresist layer PR3. A material of the second metal material layer 800 may be the same as or different from the material of the first metal material layer 700. Specifically, the material of the second metal material layer 800 is, for example, copper, titanium, tantalum, tungsten, aluminum or an alloy thereof.

After the second metal material layer 800 is formed, the third patterned photoresist layer PR3 is removed to form a second patterned conductive layer C2, as shown in FIG. 1Q. The second patterned conductive layer C2 includes a plurality of third conductive bumps 802 and a plurality of fourth conductive bumps 804. Next, referring to FIG. 1R, dry etching or wet etching is used to remove a part of the second seed layer 400b not covered by the third conductive bumps 802 or the fourth conductive bumps 804. It should be noted that, in the present embodiment, because all the openings OP2 are not disposed corresponding to the conductive pillars 602, not all the third conductive bumps 802 and the fourth conductive bumps 804 are connected to the conductive pillars 602. However, in other embodiments, all the third conductive bumps 802 and the fourth conductive bumps 804 can be electrically connected to different conductive pillars 602 respectively. Similar to the first conductive bumps 702 and the second conductive bumps 704, because the third conductive bumps 802 and the fourth conductive bumps 804 are formed by using the same third patterned photoresist layer PR3, a thickness H3 of the third conductive bumps 802 is equal to a thickness H4 of the fourth conductive bumps 804.

Next, referring to FIG. 1S, after the first conductive bumps 702 and the second conductive bumps 704 are separated from the second substrate 100b and the second buffer layer 200b, the interposer structure 10 in the present embodiment is obtained.

The interposer structure 10 in the present embodiment includes the flexible substrate 300, the conductive pillars 602, the first patterned conductive layer C1, and the second patterned conductive layer C2. The first patterned conductive layer C1 and the second patterned conductive layer C2 are respectively disposed on two opposite surfaces of the flexible substrate 300, and are electrically connected to each other by the conductive pillars 602 embedded in the flexible substrate 300. The first patterned conductive layer C1 includes the first conductive bumps 702 and the second conductive bumps 704, and the second patterned conductive layer C2 includes the third conductive bumps 802 and the fourth conductive bumps 804. In the present embodiment, the thickness H1 of the first conductive bumps 702 is the same as the thickness H2 of the second conductive bumps 704. On the other hand, the thickness H3 of the third conductive bumps 802 is the same as the thickness H4 of the fourth conductive bumps 804.

Because the interposer structure 10 in the present embodiment includes the flexible substrate 300 having a lower dielectric constant, the conductivity and heat dissipation of a semiconductor device can be effectively improved. On the other hand, since the semi-additive process is used to form the first patterned conductive layer C1 and the second patterned conductive layer C2 on two surfaces of the flexible substrate 300 of the interposer structure 10 of the present embodiment, fine traces can be effectively formed, thereby improving miniaturization of an integrated circuit.

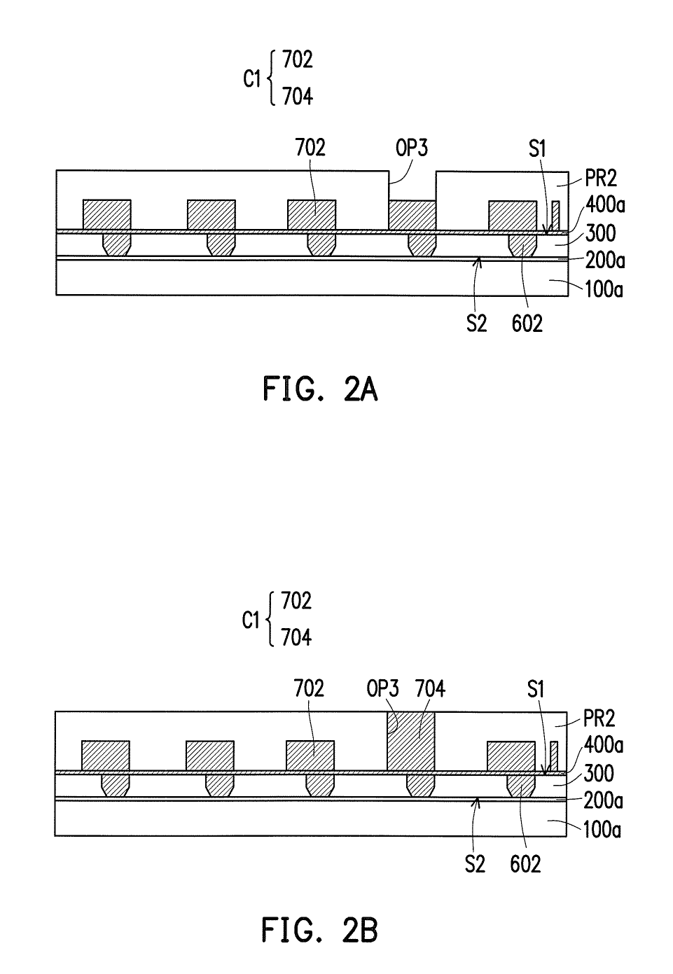

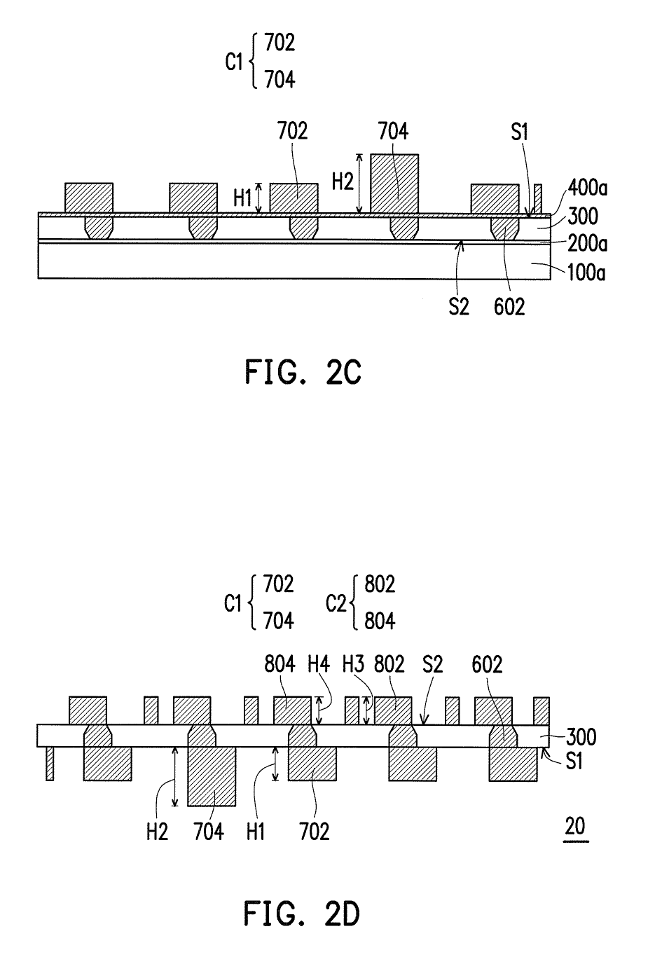

FIG. 2A to FIG. 2C are schematic cross-sectional views of part of a manufacturing process of an interposer structure 20 according to another embodiment of the present invention. FIG. 2D is a schematic cross-sectional view of the interposer structure 20 according to the embodiment in FIG. 2A to FIG. 2C. The present embodiment is similar to the embodiment in FIG. 1A to FIG. 1S, and a difference lies in that after the step of FIG. 1K is completed and before the step of FIG. 1L is performed, the present embodiment further includes steps in FIG. 2A to FIG. 2C. Specifically, in the present embodiment, after the step of FIG. 1K is completed, only the plurality of first conductive bumps 702 is formed, and the second conductive bumps 704 are formed after the steps in FIG. 2A to FIG. 2C were performed.

Referring to FIG. 2A first, a second patterned photoresist layer PR2 is formed on the first conductive bumps 702 and the first seed layer 400a. Reference may be made to the first patterned photoresist layer PR1 for a material and a forming method of the second patterned photoresist layer PR2, and the descriptions thereof are omitted herein. The second patterned photoresist layer PR2 has openings OP3, so as to expose some of the first conductive bumps 702. In other words, in the present embodiment, the second patterned photoresist layer PR2 covers some of the first conductive bumps 702 and exposes the rest of first conductive bumps 702.

Next, referring to FIG. 2B, a metal material is filled in the openings OP3 of the second patterned photoresist layer PR2 to form the second conductive bumps 704. Subsequently, the second patterned photoresist layer PR2 is removed, as shown in FIG. 2C. Because, in addition to the first patterned photoresist layer PR1, the second patterned photoresist layer PR2 is further needed to form the second conductive bumps 704, the thickness H2 of the second conductive bumps 704 is not the same as the thickness H1 of the first conductive bumps 702. More specifically, in the present embodiment, the thickness H2 of the second conductive bumps 704 is greater than the thickness H1 of the first conductive bumps 702.

After the step in FIG. 2C is completed, the steps in FIG. 1L to FIG. 1S are performed to obtain the interposer structure 20 shown in FIG. 2D. The interposer structure 20 in the present embodiment is similar to the interposer structure 10 in FIG. 1S, and a difference lies in that, for the interposer structure 20, the thickness H2 of the second conductive bumps 704 is greater than the thickness H1 of the first conductive bumps 702.

It should be noted that, in the present embodiment, the second patterned photoresist layer PR2 is formed on the first seed layer 400a after the first patterned photoresist layer PR1 is removed. In other words, the present embodiment is exemplified by the process in which the step in FIG. 1K is immediately followed by the step in FIG. 2A, but the present invention is not limited thereto. In other embodiments, the second patterned photoresist layer PR2 may also be first formed on the first patterned photoresist layer PR1 before the first patterned photoresist layer PR1 is removed, and the first patterned photoresist layer PR1 and the second patterned photoresist layer PR2 are then removed together after the second conductive bumps 704 are formed. In other words, in other embodiments, the step in FIG. 2A may also be performed immediately after the step in FIG. 1J. In addition, in other embodiments, the steps in FIG. 2A to FIG. 2D may also be performed after the steps in FIG. 1A to FIG. 1S are completed. In other words, a process of increasing the height of the second conductive bumps 704 for the first surface S1 may be performed after the processes on the first surface S1 and the second surface S2 of the flexible substrate 300 are completed.

Similar to the embodiment in FIG. 1A to FIG. 1S, because the interposer structure 20 in the present embodiment includes the flexible substrate 300 having a lower dielectric constant, the conductivity and heat dissipation of a semiconductor device can be effectively improved. On the other hand, since the semi-additive process is used to form the first patterned conductive layer C1 and the second patterned conductive layer C2 on two surfaces of the flexible substrate 300 of the interposer structure 20 of the present embodiment, fine traces can be effectively formed, thereby improving miniaturization of an integrated circuit. In addition, because in the present embodiment, the thickness H2 of the second conductive bumps 704 is different from the thickness H1 of the first conductive bumps 702, the interposer structure 20 is suitable for use on connection points having height differences. For example, other than an integrated circuit, the interposer structure 20 may also be applicable to a probe. Therefore, the interposer structure 20 in the present embodiment can be widely used for different purposes.

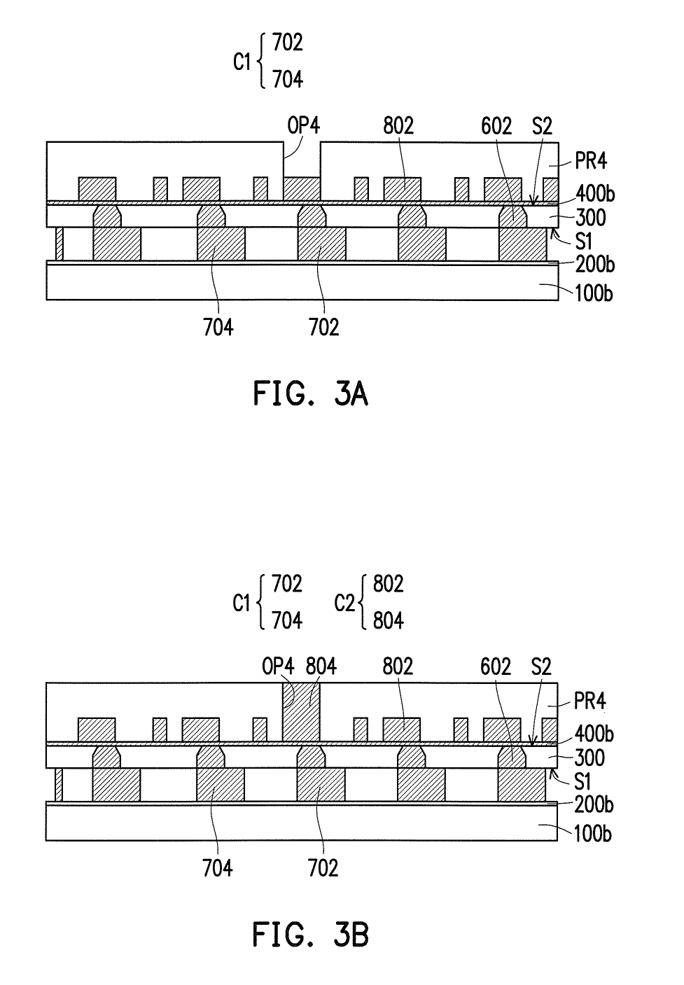

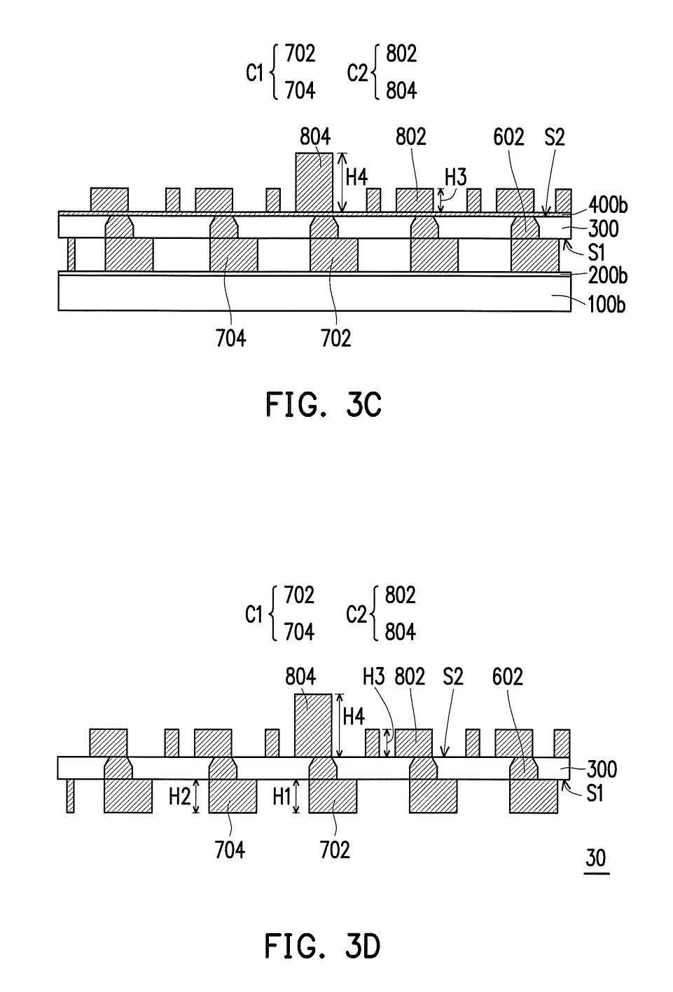

FIG. 3A to FIG. 3C are schematic cross-sectional views of part of a manufacturing process of an interposer structure according to still another embodiment of the present invention. FIG. 3D is a schematic cross-sectional view of the interposer structure according to the embodiment in FIG. 3A to FIG. 3C. The present embodiment is similar to the embodiment in FIG. 1A to FIG. 1S, and a difference lies in that after the step in FIG. 1Q is performed and before the step in FIG. 1R, the present embodiment further includes the steps in FIG. 3A to FIG. 3C. Specifically, in the present embodiment, after the step of FIG. 1Q is completed, only the plurality of third conductive bumps 802 is formed, and the fourth conductive bumps 804 are formed after the steps in FIG. 3A to FIG. 3C were performed.

Referring to FIG. 3A first, a fourth patterned photoresist layer PR4 is formed on the third conductive bumps 802 and the second seed layer 400b. Reference may be made to a material and a forming method of the fourth patterned photoresist layer PR4 for the third patterned photoresist layer PR3, and the descriptions thereof are omitted herein. The fourth patterned photoresist layer PR4 has openings OP4, so as to expose some of the third conductive bumps 802. In other words, in the present embodiment, the fourth patterned photoresist layer PR4 covers some of the third conductive bumps 802 and exposes the rest of third conductive bumps 802.

Next, referring to FIG. 3B, a metal material is filled in the openings OP4 of the fourth patterned photoresist layer PR4 to form the fourth conductive bumps 804. Subsequently, the fourth patterned photoresist layer PR4 is removed, as shown in FIG. 3C. Because, in addition to the third patterned photoresist layer PR3, the fourth patterned photoresist layer PR4 is further needed to form the fourth conductive bumps 704, the thickness H4 of the fourth conductive bumps 804 is different from the thickness H3 of the third conductive bumps 802. More specifically, in the present embodiment, the thickness H4 of the fourth conductive bumps 804 is greater than the thickness H3 of the third conductive bumps 802.

After the step in FIG. 3C is completed, the steps in FIG. 1R to FIG. 1S are performed, so as to obtain an interposer structure 30 shown in FIG. 3D. The interposer structure 30 in the present embodiment is similar to the interposer structure 10 in FIG. 1S, and a difference lies in that, for the interposer structure 30, the thickness H4 of the fourth conductive bumps 804 is greater than the thickness H3 of the third conductive bumps 802.

It should be noted that, in the present embodiment, the fourth patterned photoresist layer PR4 is formed on the second seed layer 400b after the third patterned photoresist layer PR3 is removed. In other words, the present embodiment is exemplified by the process in which the step in FIG. 1Q is immediately followed by the step in FIG. 3A, but the present invention is not limited thereto. In other embodiments, the fourth patterned photoresist layer PR4 may also be first formed on the third patterned photoresist layer PR3 before the third patterned photoresist layer PR3 is removed, and the third patterned photoresist layer PR3 and the fourth patterned photoresist layer PR4 are then removed together after the fourth conductive bumps 804 are formed. In other words, in other embodiments, the step in FIG. 3A may also be performed immediately after the step in FIG. 1P. In addition, in other embodiments, the steps in FIG. 3A to FIG. 3D may also be performed after the steps in FIG. 1A to FIG. 1S are completed. In other words, a process of increasing the height of the fourth conductive bumps 804 for the first surface S1 may be performed after the processes on the first surface S1 and the second surface S2 of the flexible substrate 300 are completed.

Similar to the embodiment in FIG. 1A to FIG. 1S, because the interposer structure 30 in the present embodiment includes the flexible substrate 300 having a lower dielectric constant, the conductivity and heat dissipation of a semiconductor device can be effectively improved. On the other hand, since the semi-additive process is used to form the first patterned conductive layer C1 and the second patterned conductive layer C2 on two surfaces of the flexible substrate 300 of the interposer structure 30 of the present embodiment, fine traces can be effectively formed, thereby improving miniaturization of an integrated circuit. In addition, because in the present embodiment, the thickness H4 of the fourth conductive bumps 804 is different from the thickness H3 of the third conductive bumps 802, the interposer structure 30 is suitable for use on connection points having height differences. For example, other than an integrated circuit, the interposer structure 30 may also be applicable to a probe. Therefore, the interposer structure 30 in the present embodiment can be widely used for different purposes.

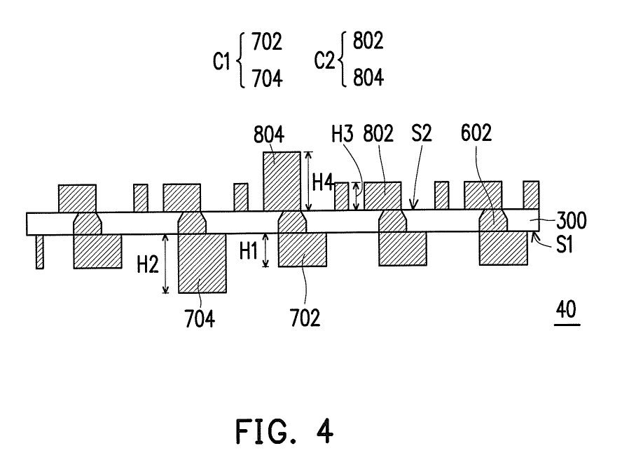

FIG. 4 is a schematic cross-sectional view of an interposer structure according to yet another embodiment of the present invention. The present embodiment is similar to the foregoing three embodiments, and a difference lies in that in the present embodiment, after the steps in FIG. 1A to FIG. 1K are completed, the steps in FIG. 2A to FIG. 2C are first performed, the steps in FIG. 1L to FIG. 1Q are performed next; after the step in FIG. 1Q is completed, the steps in FIG. 3A to FIG. 3C are then performed, and subsequently the steps in FIG. 1R and FIG. 1S are performed, so as to obtain an interposer structure 40 shown in FIG. 4. In other words, the interposer structure 40 in the present embodiment is similar to the interposer structure 10 in FIG. 1S, and a difference lies in that for the interposer structure 40, the thickness H2 of the second conductive bumps 704 is greater than the thickness H1 of the first conductive bumps 702, and the thickness H4 of the fourth conductive bumps 804 is greater than the thickness H3 of the third conductive bumps 802.

Similar to the embodiment in FIG. 1A to FIG. 1S, because the interposer structure 40 in the present embodiment includes the flexible substrate 300 having a lower dielectric constant, the conductivity and heat dissipation of a semiconductor device can be effectively improved. On the other hand, since the semi-additive process is used to form the first patterned conductive layer C1 and the second patterned conductive layer C2 on two surfaces of the flexible substrate 300 of the interposer structure 40 of the present embodiment, fine traces can be effectively formed, thereby improving miniaturization of an integrated circuit. In addition, because in the present embodiment, the thickness H2 of the second conductive bumps 704 is different from the thickness H1 of the first conductive bumps 702, and the thickness H4 of the fourth conductive bumps 804 is also different from the thickness H3 of the third conductive bumps 802, both surfaces of the interposer structure 40 can be suitable for use on connection points having height differences. For example, other than an integrated circuit, the interposer structure 40 may also be applicable to a probe. Therefore, the interposer structure 40 in the present embodiment can be widely used for different purposes.

Based on the foregoing, in the interposer structure of the present invention, by using the flexible substrate having a lower dielectric constant, the conductivity and heat dissipation of the interposer structure can be effectively improved, thereby providing a semiconductor device with higher reliability. In another aspect, since the interposer structure of the present invention includes metal bumps having different heights, the interposer structure can be suitable for use on connection points having height differences, and is therefore applicable for wider uses.

Although the present invention has been disclosed above by using the embodiments, the embodiments are not used to limit the present invention, and any person of ordinary skill can make several variations and modifications without departing from the spirit and scope of the present invention. Therefore, the protection scope of the present invention should be as defined by the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An interposer structure, comprising:
a flexible substrate, comprising a first surface and a second surface opposite to the first surface, the flexible substrate comprising a plurality of through holes, and the through holes extending from the first surface to the second surface, wherein a material of the flexible substrate is an insulator;
a plurality of conductive pillars, disposed in the through holes;
a first patterned conductive layer, disposed on the first surface of the flexible substrate and electrically connected to the conductive pillars; and
a second patterned conductive layer, disposed on the second surface of the flexible substrate and electrically connected to the conductive pillars.

2. The interposer structure according to claim 1, wherein the first patterned conductive layer further comprises a plurality of first conductive bumps and a plurality of second conductive bumps, at least one of the first conductive bumps and the second conductive bumps is electrically connected to the conductive pillars, the second patterned conductive layer further comprises a plurality of third conductive bumps and a plurality of fourth conductive bumps, and at least one of the third conductive bumps and the fourth conductive bumps is electrically connected to the conductive pillars.

3. The interposer structure according to claim 2, wherein the first conductive bumps and the second conductive bumps comprise a same thickness.

4. The interposer structure according to claim 2, wherein the first conductive bumps and the second conductive bumps comprise different thicknesses.

5. The interposer structure according to claim 1, wherein the material of the flexible substrate is polyimide (PI) or polyethylene terephthalate (PET).

6. The interposer structure according to claim 1, wherein a thickness of the flexible substrate is 7.5 μm to 400 μm.

7. A manufacturing method of an interposer structure, comprising:
providing a flexible substrate, wherein the flexible substrate comprises a first surface and a second surface opposite to the first surface, and a material of the flexible substrate is an insulator;
forming a plurality of through holes in the flexible substrate;
forming a first seed layer on the first surface and in the through holes of the flexible substrate;
filling a conductive material in the through holes to form a plurality of conductive pillars;
forming a first patterned conductive layer on the first seed layer, wherein the first patterned conductive layer is electrically connected to the conductive pillars;
removing the first seed layer;
forming a second seed layer on the second surface of the flexible substrate;
forming a second patterned conductive layer on the second seed layer, wherein the second patterned conductive layer is electrically connected to the conductive pillars; and
removing the second seed layer.

8. The manufacturing method of an interposer structure according to claim 7, wherein the step of forming the first patterned conductive layer comprises:
forming a first patterned photoresist layer on the first seed layer, wherein the first patterned photoresist layer comprises a plurality of openings;
filling a first metal layer material in the openings; and
removing the first patterned photoresist layer to form the first patterned conductive layer.

9. The manufacturing method of an interposer structure according to claim 7, wherein the step of forming the first patterned conductive layer comprises:
forming a first patterned photoresist layer on the first seed layer, wherein the first patterned photoresist layer comprises a plurality of openings;
filling a first metal layer material in the openings;
removing the first patterned photoresist layer to form a plurality of first conductive bumps;
forming a second patterned photoresist layer on the first surface of the flexible substrate, wherein the second patterned photoresist layer exposes at least one of the first conductive bumps;
forming a metal material on the exposed first conductive bumps to form a plurality of second conductive bumps; and
removing the second patterned photoresist layer to form the first patterned conductive layer, wherein the first patterned conductive layer comprises the first conductive bumps and the second conductive bumps.

10. The manufacturing method of an interposer structure according to claim 9, wherein a thickness of the second conductive bumps is greater than a thickness of the first conductive bumps.

11. The manufacturing method of an interposer structure according to claim 7, wherein the material of the flexible substrate is polyimide (PI) or polyethylene terephthalate (PET).
